(19) United States
(12) Patent Application Publication
(10) Pub. No.: US 2026/0160495 A1
(43) Pub. Date: Jun. 11, 2026

(54) SINTERING FURNACE

(71) Applicant: Illinois Tool Works Inc., Glenview, IL (US)

(72) Inventors: Shenghu YAN, Suzhou (CN); Wenhua SU, Suzhou (CN)

(21) Appl. No.: 18/850,467

(22) PCT Filed: Mar. 24, 2023
(86) PCT No.: PCT/US2023/016324

§ 371 Date: Sep. 24, 2024

(51) Int. Cl. F27B 9/10; B01D 53/34; B01D 53/76; F23G 7/06; F27B 9/30; F27D 7/04; F27D 13/00; F27D 17/17; H10P 72/00

(52) U.S. Cl. CPC F27B 9/10; B01D 53/343; B01D 53/76; F23G 7/061; F27B 9/3077; F27D 7/04; F27D 13/00; F27D 17/17; H10P 72/0434; B01D 2258/0216; F23G 2206/10; F27B 2009/3088; F27D 2007/045

(57) ABSTRACT

The present application discloses a sintering furnace including a furnace chamber; an incineration device, the incineration device configured to be capable of heating exhaust gas to incineration to obtain purified gas; and a heat exchange device, wherein the heat exchange device is configured such that clean gas is heat exchanged with the purified gas to heat the clean gas and cool the purified gas prior to input into the furnace chamber. The sintering furnace of the present application uses high temperature gas discharged from the incineration device to heat the clean gas so that the clean gas can reach a preset temperature before being input into the furnace chamber, thereby reducing the number of heating elements required in the furnace chamber and taking advantage of residual heat of the high temperature gas discharged from the incineration device to reduce energy consumption.

### TECHNICAL FIELD

The present disclosure relates to a sintering furnace, in particular to a sintering furnace for processing photovoltaic devices.

### BACKGROUND

In the production of photovoltaic devices such as silicon wafers of crystalline silicon solar cells, a sintering furnace is required to sinter the photovoltaic devices. The sintering furnace typically includes a drying section, a sintering section, and a cooling section. Here, photovoltaic devices printed with paste such as silver paste are transported by a conveyor belt through the drying section, the sintering section and the cooling section in this order, and then transported out of the sintering furnace by the conveyor belt.

### SUMMARY

At least one object of the present application is to provide a sintering furnace, including a furnace chamber, including a gas outlet and a gas inlet, where the gas outlet is configured to discharge exhaust gas in the furnace chamber, and the gas inlet is configured to input clean gas into the furnace chamber; an incineration device in fluid communication with the gas outlet of the furnace chamber, the incineration device configured to be capable of receiving exhaust gas discharged from the gas outlet of the furnace chamber and heating the exhaust gas to incineration to provide purified gas; and a heat exchange device in fluid communication with the gas outlet through the incineration device and the heat exchange device in fluid communication with the gas inlet, where the heat exchange device is configured such that the clean gas is heat exchanged with the purified gas to heat the clean gas and cool the purified gas prior to input into the furnace chamber.

According to the above, the heat exchange device includes a first gas channel configured to circulate the clean gas and a second gas channel configured to circulate the purified gas, and the heat exchange device is configured to cause the clean gas in the first gas channel and the purified gas in the second gas channel to be heat exchanged.

According to the above, the sintering furnace further includes a drive device configured to drive the clean gas to enter the furnace chamber again after flowing through the heat exchange device for heating.

According to the above, the drive device is a fan configured to cause the clean gas to be heated to a preset temperature in the heat exchange device by adjusting power of the fan.

According to the above, the sintering furnace further includes a heating device disposed between the gas inlet of the furnace chamber and the heat exchange device, the heating device configured to heat the clean gas discharged from the heat exchange device so that the clean gas reaches a preset temperature.

According to the above, the furnace chamber includes a drying section, a sintering section, and a cooling section, where the gas inlet and the gas outlet of the furnace chamber are provided on the drying section.

According to the above, the heat exchange device includes: a housing having a heat exchange cavity within the housing; and several heat exchange tubes disposed substantially parallel along its length direction within the heat exchange cavity; where the interior of the several heat exchange tubes forms a portion of the first gas channel, and the heat exchange cavity outside the several heat exchange tubes forms the second gas channel.

According to the above, the heat exchange device further includes: a first box and a second box disposed at both ends in the length direction of the several heat exchange tubes and in fluid communication with the interior of each of the several heat exchange tubes; and a clean gas inlet and a clean gas outlet, wherein the clean gas inlet is configured to receive clean gas, and the clean gas outlet is in fluid communication with the gas inlet of the furnace chamber; where the first box and the clean gas inlet are in fluid communication, the second box and the clean gas outlet are in fluid communication, and the first box and the second box form another portion of the first gas channel.

According to the above, the heat exchange device further includes: a pair of tube plates connected at both ends in the length direction of the several heat exchange tubes, respectively; and several split partitions disposed laterally in the first and second boxes; where the several split partitions are configured such that the several heat exchange tubes have at least two tube passes.

According to the above, the several heat exchange tubes are arranged in rows, and the heat exchange tubes in two adjacent rows are staggered.

Other objects and advantages of the present application will be apparent from the description of the present application hereinafter with reference to the accompanying drawings, and may help with a full understanding of the present application.

### BRIEF DESCRIPTION OF DRAWINGS

FIG. 1 is a schematic structural diagram of a sintering furnace according to an example of the present application;

FIG. 2A is a perspective view of a drying section of FIG. 1;

FIG. 2B is an exploded view of the drying section of FIG. 1;

FIG. 3A is a perspective view of a heat exchange device of FIG. 1 viewed from the front;

FIG. 3B is a perspective view of the heat exchange device of FIG. 1 viewed from the rear;

FIG. 4A is a top view of the heat exchange device of FIG. 1;

FIG. 4B is a cross-sectional view of the heat exchange device of FIG. 4A along line A-A; and

FIG. 4C is a cross-sectional view of the heat exchange device of FIG. 4A along line B-B.

### DETAILED DESCRIPTION

Various specific examples of the present application will be described below with reference to the attached drawings that form a part of the present specification. It should be understood that while terms denoting orientation, such as “front,” “rear,” “upper,” “lower,” “left,” “right,” “top,” “bottom,” “inside,” “outside,” etc., are used in the present application to describe various exemplary structural parts and elements of the present application, these terms are used herein for convenience of illustration only and are determined based on the exemplary orientations shown in the attached drawings. Since the examples disclosed in the present application may be disposed in different orientations, these terms denoting orientation are for illustrative purposes only and should not be considered as limiting.

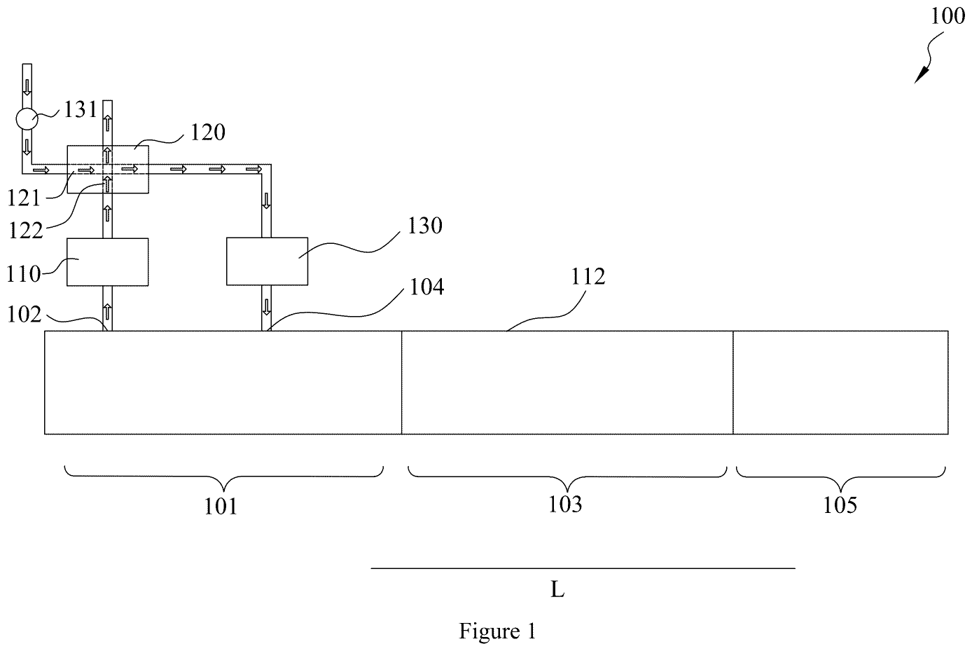

FIG. 1 is a schematic structural diagram of a sintering furnace 100 according to an example of the present application. As shown in FIG. 1, the sintering furnace 100 includes a furnace chamber 112 including a drying section 101, a sintering section 103, and a cooling section 105 in fluid communication with each other, and a photovoltaic device (not shown in the figure) being transported by a conveying device (not shown in the figure) passes the drying section 101, the sintering section 103, and the cooling section 105 sequentially from the left end of the furnace chamber 112, and is outputted from the furnace 100 from the right end of the furnace chamber 112 to complete a sintering process. In the drying section 101, the organic matter or the like in the slurry printed on the photovoltaic device can volatilize. In the sintering section 103, the electrode materials and silicon on the photovoltaic device are heated to a eutectic temperature, and the silicon atoms are dissolved in proportion into the electrode materials in a molten state. In the cooling section 105, the silicon atoms dissolved in the electrode materials of the photovoltaic device are re-crystallized in a solid form such that an ohmic contact is formed between the electrode and the silicon, resulting in a solar cell.

The furnace chamber 112 also includes a gas inlet 104 and a gas outlet 102. Exhaust gas in the furnace chamber 112 is discharged from the gas outlet 102 and clean gas is input from the gas inlet 104 to complete circulation of gas in the furnace chamber 112 to maintain gas pressure in the furnace chamber 112 within a certain range. In this example, since the organic matter in the slurry printed by the photovoltaic device is volatilized in the drying section 101, the gas inlet 104 and the gas outlet 102 may be provided on the drying section 101.

The sintering furnace 100 also includes an incineration device 110 and a heat exchange device 120. The incineration device 110 is in fluid communication with the gas outlet 102 to receive exhaust gas in the furnace chamber 112 discharged from the gas outlet 102. The exhaust gas discharged from the furnace chamber 112 through the gas outlet 102 mainly includes organic matters, which can be purified by heating and incineration by the incineration device 110. In this example, main components of the purified gas obtained from the organic matters after incineration treatment are carbon dioxide and water.

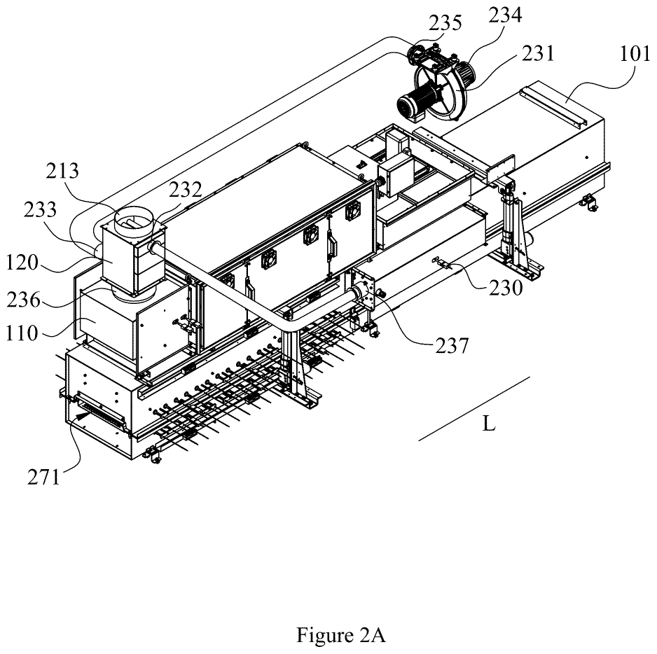

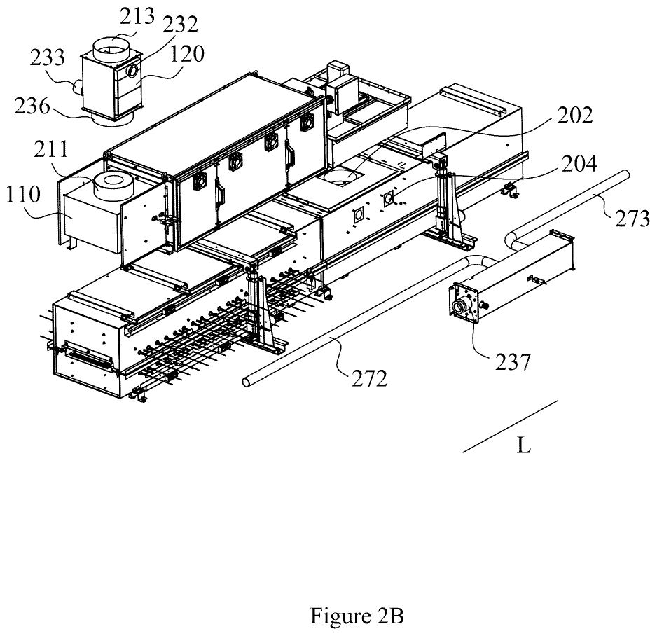

The interior of the heat exchange device 120 includes a first gas channel 121 and a second gas channel 122, gas in the first gas channel 121 and gas in the second gas channel 122 being capable of heat exchange. The incineration device 110 is in fluid communication with the second gas channel 122 so that purified gas discharged from an outlet conduit 211 of the incineration device (see FIGS. 2A and 2B) can flow through the second gas channel 122 of the heat exchange device 120. The first gas channel 121 is in fluid communication with the gas inlet 104 to circulate clean gas to be input into the furnace chamber 112. In this example, the clean gas is air in the outside environment. The air in the external environment is driven by a drive device 131, to flow through the first gas channel 121, and enter the furnace chamber 112 from the gas inlet 104.

In this example, the gas temperature at the outlet of the incineration device 110 is approximately 750° C., that is, the gas temperature in the second gas channel 122 is approximately 750° C. The temperature of the air that is driven into the first gas channel 121 by the drive device 131 is room temperature, about 25° C. The air in the first gas channel 121 is heat exchanged with the purified gas in the second gas channel 122 inside the heat exchange device 120 such that the air can be heated before being input into the furnace chamber 112 and the purified gas can be cooled. As one specific example, both the air and the purified gas after the heat exchange is completed are about 400° C. After the heat exchange is complete, the purified gas can be mixed with outside air to cool down and discharged directly to the outside or to a plant exhaust conduit. However, the air may be input directly into the furnace chamber 112 from the gas inlet 104.

As a more specific example, the drive device 131 may be a fan, and by controlling power of the fan, velocity of air circulation in the first gas channel 121 may be adjusted, thereby adjusting the temperature to which the air is heated. For example, when the flow rate of the purified gas discharged by the incineration device 110 is certain, the temperature of the heated air is lower after the heat exchange is completed when the velocity of air circulation in the first gas channel 121 is faster. When the velocity of air circulation in the first gas channel 121 is slower, the temperature of the heated air is also higher after the heat exchange is completed.

It will be appreciated by those skilled in the art that in some other examples, the clean gas may also be inert gas, depending on the gas atmosphere required by the sintering furnace 100.

Some heating devices need to be provided in the general drying section 101 to heat the gas in the drying section 101 so that the organic matters in the slurry printed on the photovoltaic device can be dried. By providing the heat exchange device 120, the heat of the purified gas after treatment by the incineration device 110 can be fully utilized, so that the gas in the drying section 101 can be heated to a preset temperature before being input into the drying section 101 of the furnace chamber 112.

In this example, the preset temperature of the clean gas is approximately 400° C. to meet the temperature requirement of the gas in the drying section 101. In some other examples, specific locations of the gas inlet 104 and the gas outlet 102 may also be set according to actual needs, and the preset temperature of the clean gas may be adjusted. For example, if the gas inlet 104 is disposed on the sintering section 103, the preset temperature needs to meet the temperature requirement of the gas in the sintering section 103.

In order to ensure that the clean gas inputted into the furnace chamber 112 from the gas inlet 104 can reach the desired preset temperature, in some examples, the sintering furnace 100 can further include a heating device 130 disposed between the first gas channel 121 of the heat exchange device 120 and the gas inlet 104 for further heating the heated clean gas discharged from the heat exchange device 120, so that the gas input into the furnace chamber 112 can reach the respective preset temperature.

FIGS. 2A and 2B illustrate the specific structure of the drying section 101 of the sintering furnace 100, where FIG. 2A is a perspective view of the drying section 101 and FIG. 2B is an exploded view of the drying section 101. To clearly show the structure of the drying section 101, the sintering section 103 and the cooling section 105 of the sinter furnace 100, and the housing of the sinter furnace 100 are omitted in FIGS. 2A and 2B, and the fan 231 and a portion of the conduit are omitted in FIG. 2B. As shown in FIG. 2, the drying section 101 has a length direction L, and the photovoltaic device enters the drying section 101 from an inlet 271 at the left end of the drying section 101 and is transported to the right along the length direction L. The incineration device 110 is provided above the top of the drying section 101 and in fluid communication with the interior of the drying section 101 through the gas outlet 202 at the top of the drying section 101. The incineration device 110 has an outlet conduit 211 from which the purified gas is discharged after exhaust gas discharged from the drying section 101 is heated to incineration by the incineration device 110.

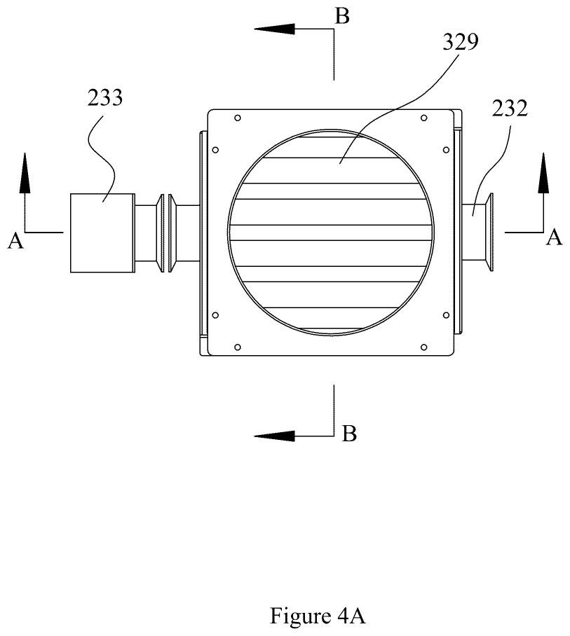

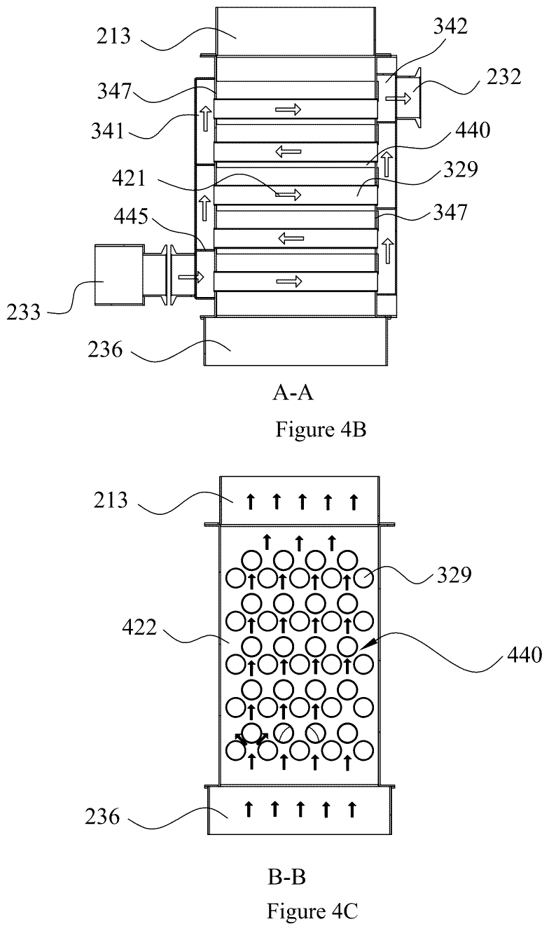

The heat exchange device 120 is disposed above the incineration device 110 with a purified gas inlet 236 at the bottom, a purified gas outlet 213 at the opposite top, the purified gas inlet 236 and the purified gas outlet 213 being in fluid communication through a second gas channel 422 (see FIGS. 4B and 4C) inside the heat exchange device 120. The purified gas inlet 236 is in fluid communication with the outlet conduit 211 of the incineration device 110, and the purified gas outlet 213 is connected to the plant exhaust conduit by another gas cooling device (not shown).

The opposite front and rear sides of the heat exchange device 120 are provided with a clean gas inlet 233 and a clean gas outlet 232, which are in fluid communication through a first gas channel 421 (see FIGS. 4B and 4C) inside the heat exchange device 120. The clean gas inlet 233 is in fluid communication with an outlet end 235 of the fan 231, and an inlet end 234 of the fan 231 is in air communication with the outside world. The clean gas outlet 232 is in fluid communication with the gas inlet 204 on the drying section 101 through a conduit 237. In this example, there are two gas inlets 204, and a conduit 272 and a conduit 273 connected to the conduit 237 extend into the interior of the drying section 101 from the two gas inlets 204, respectively, and extend towards both ends of the drying section 101 in the length direction L, respectively. A heating device 230 is provided on the conduit 237.

As such, the exhaust gas discharged from the gas outlet 202 of the drying section 101 is heated to incineration by the incineration device 110 to obtain purified gas, the purified gas enters from the outlet conduit 211 to the purified gas inlet 236 of the heat exchange device 120, and then flows through the second gas channel 422 (see FIGS. 4B and 4C) before being discharged from the purified gas outlet 213. The external air flows from the inlet end 234 to the outlet end 235 under the driving of the fan 231, then from the clean gas inlet 233 into the heat exchange device 120, through the first gas channel 421 (see FIGS. 4B and 4C), from the clean gas outlet 232 to the conduit 237, and along the conduit 272 and the conduit 273 from the two gas inlets 204 into the drying section 101, and flows in the drying section 101 towards both ends of the drying section 101 in the length direction L. The air flowing through the first gas channel 421 and the purified gas flowing through the second gas channel 422 can be heat exchanged in the heat exchange device 120 to heat the air and cool the purified gas.

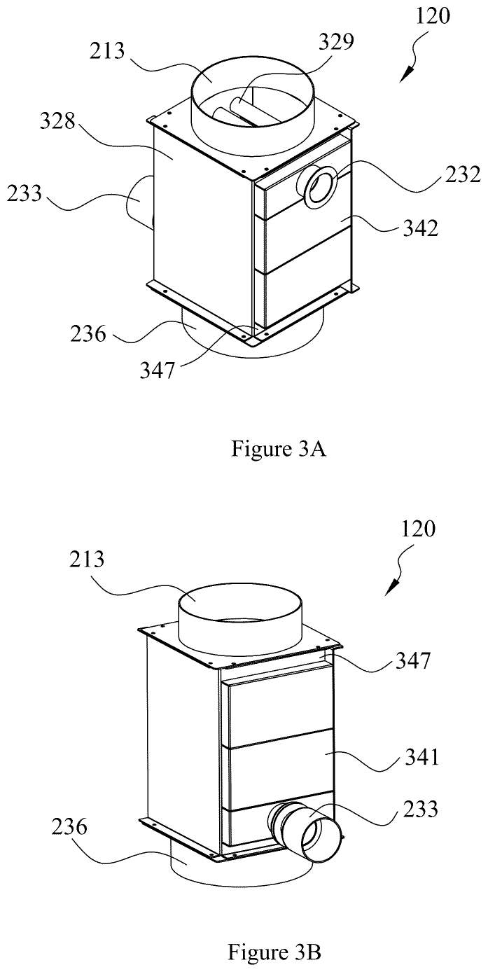

FIGS. 3A and 3B illustrate the exterior structure of the heat exchange device 120, where FIG. 3A is a perspective view of the heat exchange device 120 viewed from the front and FIG. 3B is a perspective view of the heat exchange device 120 viewed from the rear. As shown in FIGS. 3A and 3B, the heat exchange device 120 includes a hollow housing 328 that is substantially cuboid-shaped, the purified gas inlet 236 is provided at the bottom of the housing 328, and the purified gas outlet 213 is provided at the top of the housing 328. Inside the housing 328 is provided several heat exchange tubes 329 extending in a front-to-back direction.

The heat exchange device 120 also includes a pair of tube plates 347, a front box 342 (i.e., a second box), and a rear box 341 (i.e., a first box). The pair of tube plates 347 are respectively provided on the front and rear sides of the housing 328 for enclosing the housing 328 in the front-to-back direction and supporting the heat exchange tube 329 within the housing 328. The front and rear boxes 342, 341 are respectively disposed outside of the pair of tube plates 347. The front and rear boxes 342, 341 are in hollow square box shapes, the front box 342 is provided on the front side of the housing 328, and the rear box 341 is provided on the rear side of the housing 328. The clean gas inlet 233 is provided on the rear box 341 and in fluid communication with the interior of the rear box 341, and the clean gas outlet 232 is provided on the front box 342 and in fluid communication with the interior of the front box 342.

FIGS. 4A-4C illustrate the internal structure of the heat exchange device 120, where FIG. 4A is a top view of the heat exchange device 120 and FIG. 4B is a cross-sectional view of the heat exchange device 120 of FIG. 4A along line A-A for illustrating the first gas channel 421. FIG. 4C is a cross-sectional view of the heat exchange device 120 of FIG. 4A along line B-B for illustrating the second gas channel 422. As shown in FIGS. 4A-4C, the housing 328 of the heat exchange device 120 has a heat exchange cavity 440 inside, and the heat exchange tube 329 is disposed in the heat exchange cavity 440. In this example, the interior of the housing 328 between the pair of tube plates 347 forms the heat exchange cavity 440. Both ends in the length direction of the heat exchange tube 329 are supported on the tube plate 347 and are in fluid communication with the front and rear boxes 342, 341 through the tube plate 347. The heat exchange tube 329 is used internally to circulate clean gas. The interior of the front box 342, the rear box 341, and the heat exchange tube 329 collectively form the first gas channel 421. As such, outside air enters the first gas channel 421 of the heat exchange device 120 from the clean gas inlet 233 through the rear box 341, and then exits the clean gas outlet 232 through the front box 342 after heat exchange, in the first gas channel 421, with the purified gas in the second gas channel 422.

The heat exchange device 120 also includes several split partitions 445 disposed laterally in the front and rear boxes 342, 341 to separate the front and rear boxes 342, 341 into several areas, respectively. As such, the heat exchange tube 329 can have a plurality of tube passes to increase the flow distance of air in the first gas channel 421, thereby improving heat exchange efficiency. In this example, two split partitions 445 are provided in each of the front and rear boxes 342, 341 such that the heat exchange tube 329 has five tube passes. In other examples, other numbers of split partitions 445 may be provided so that the heat exchange tube 329 has more or less tube passes.

The heat exchange cavity 440 external to the heat exchange tube 329 is used to form the second gas channel 422. After the purified gas enters the second gas channel 422 from the purified gas inlet 236, it flows upwards to heat exchange, in the second gas channel 422, with air in the first gas channel 421 and then is discharged from the purified gas outlet 213. In this example, the purified gas external to the heat exchange device tube 329 and the air inside the heat exchange tube 329 are heat exchanged through walls of the heat exchange tube 329. Heat exchange tubes 329 are arranged in rows spaced apart, and two adjacent rows of heat exchange tubes 329 are staggered. That is, the heat exchange tubes 329 are arranged generally as a triangular array to enable the purified gas to flow through the gap of adjacent heat exchange tubes 329, and the purified gas needs to flow through each row of heat exchange tubes 329, thereby enabling an increase in heat exchange efficiency of the purified gas.

In this example, the air in the first gas channel 421 and the purified gas in the second gas channel 422 flow in different directions for heat exchange, which can improve the heat exchange efficiency between gas. In addition, by providing the split partition 445, the air in the first gas channel 421 can have a longer flow path, and by setting the arrangement of the heat exchange tube 329, the purified gas in the second gas channel 422 can have a more tortuous flow path, thereby enabling the air and purified gas to be more fully heat exchanged.

It will be appreciated by those skilled in the art that the heat exchange device may also be a gas-gas heat exchange device of other structures that enables sufficient heat exchange of the gas in the first gas channel with the gas in the second gas channel.

In some existing sintering furnaces, on one hand, the temperature of the clean gas entered in the furnace chamber is generally room temperature, and the gas in the furnace chamber is then heated by a heating element provided in the furnace chamber so that the gas in the furnace chamber reaches a certain temperature, thereby treating the photovoltaic device as desired. On the other hand, the temperature of the gas discharged from the incineration device is high and needs to be mixed with low temperature gas before it can be discharged outwards.

The sintering furnace of the present application uses high temperature gas discharged from the incineration device to heat the clean gas so that the clean gas can reach a preset temperature before being input into the furnace chamber, thereby reducing the number of heating elements required in the furnace chamber and taking advantage of residual heat of the high temperature gas discharged from the incineration device to reduce energy consumption. Moreover, the heat exchange device of the present application has a simple structure, and the heat exchange efficiency between gas is high. By controlling the power of the fan, the air can basically be heated to the desired temperature. In addition, the sintering furnace of the present application can be retrofitted on the basis of the existing sintering furnace, with the addition of components such as heat exchange devices, and the retrofit costs are low.

Although the present disclosure has been described in connection with examples of the examples outlined above, various alternatives, modifications, variations, improvements, and/or substantial equivalents, whether known or foreseeable now or in the near future, may be apparent to those having at least ordinary skill in the art. In addition, the technical effects and/or technical problems described in the present specification are exemplary and not limiting; therefore, the disclosure in the present specification may be used to solve other technical problems and have other technical effects and/or may solve other technical problems. Therefore, examples of the present disclosure as set forth above are intended to be illustrative and not limiting. Various changes may be made without departing from the spirit or scope of the present disclosure. Therefore, the present disclosure is intended to include all known or earlier developed alternatives, modifications, variations, improvements and/or substantial equivalents.

What is claimed is:

1. A sintering furnace, comprising:
a furnace chamber, comprising a gas outlet and a gas inlet, wherein the gas outlet is configured to discharge exhaust gas in the furnace chamber, and the gas inlet is configured to input clean gas into the furnace chamber;
an incineration device in fluid communication with the gas outlet of the furnace chamber, the incineration device configured to be capable of receiving exhaust gas discharged from the gas outlet of the furnace chamber and heating the exhaust gas to incineration to provide purified gas; and
a heat exchange device in fluid communication with the gas outlet through the incineration device and the heat exchange device in fluid communication with the gas inlet, wherein the heat exchange device is configured such that the clean gas is heat exchanged with the purified gas to heat the clean gas and cool the purified gas prior to input into the furnace chamber.

2. The sintering furnace according to claim 1, wherein:
the heat exchange device comprises a first gas channel configured to circulate the clean gas and a second gas channel configured to circulate the purified gas, and the heat exchange device is configured to cause the clean gas in the first gas channel and the purified gas in the second gas channel to be heat exchanged.

3. The sintering furnace according to claim 2, wherein:
the sintering furnace further comprises a drive device configured to drive the clean gas to enter the furnace chamber again after flowing through the heat exchange device for heating.

4. The sintering furnace according to claim 3, wherein:
the drive device is a fan configured to cause the clean gas to be heated to a preset temperature in the heat exchange device by adjusting power of the fan.

5. The sintering furnace according to claim 3, wherein:
the sintering furnace further comprises a heating device disposed between the gas inlet of the furnace chamber and the heat exchange device, the heating device configured to heat the clean gas discharged from the heat exchange device so that the clean gas reaches a preset temperature.

6. The sintering furnace according to claim 1, wherein:
the furnace chamber comprises a drying section, a sintering section, and a cooling section, wherein the gas inlet and the gas outlet of the furnace chamber are provided on the drying section.

7. The sintering furnace according to claim 2, wherein:
the heat exchange device comprises:
a housing having a heat exchange cavity within the housing; and
several heat exchange tubes disposed substantially parallel along its length direction within the heat exchange cavity;
wherein the interior of the several heat exchange tubes forms a portion of the first gas channel, and the heat exchange cavity outside the several heat exchange tubes forms the second gas channel.

8. The sintering furnace according to claim 7, wherein:
the heat exchange device further comprises:
a first box and a second box disposed at both ends in the length direction of the several heat exchange tubes and in fluid communication with the interior of each of the several heat exchange tubes; and
a clean gas inlet and a clean gas outlet, wherein the clean gas inlet is configured to receive clean gas, and the clean gas outlet is in fluid communication with the gas inlet of the furnace chamber;
wherein the first box and the clean gas inlet are in fluid communication, the second box and the clean gas outlet are in fluid communication, and the first box and the second box form another portion of the first gas channel.

9. The sintering furnace according to claim 8, wherein:
the heat exchange device further comprises:
a pair of tube plates connected at both ends in the length direction of the several heat exchange tubes, respectively; and
several split partitions disposed laterally in the first and second boxes;
wherein the several split partitions are configured such that the several heat exchange tubes have at least two tube passes.

10. The sintering furnace according to claim 7, wherein:
the several heat exchange tubes are arranged in rows, and the heat exchange tubes in two adjacent rows are staggered.
